(19) United States
(12) Patent Application Publication
(10) Pub. No.: US 2024/0099078 A1
(43) Pub. Date: Mar. 21, 2024

(54) DISPLAY APPARATUS AND METHOD OF MANUFACTURING THE SAME

(71) Applicant: Samsung Display Co., Ltd., Yongin-si (KR)

(72) Inventors: Jongjun Baek, Yongin-si (KR); Jongoh Seo, Yongin-si (KR)

(21) Appl. No.: 18/243,004

(22) Filed: Sep. 6, 2023

(30) Foreign Application Priority Data
Sep. 21, 2022 (KR) 10-2022-0119539

(51) Int. Cl. H10K 59/124; H10K 59/12

(52) U.S. Cl. CPC H10K 59/124; H10K 59/1201

(57) ABSTRACT

A display apparatus includes: a substrate; a buffer layer on the substrate; a first semiconductor layer on the buffer layer; a first gate insulating layer on the first semiconductor layer; a first metal layer on the first gate insulating layer; a second gate insulating layer on the first metal layer; a second metal layer on the second gate insulating layer; a first interlayer insulating layer on the second metal layer; and a first dopant doped in at least one of the second gate insulating layer or the first interlayer insulating layer.

### CROSS-REFERENCE TO RELATED APPLICATION

This application claims priority to and the benefit of Korean Patent Application No. 10-2022-0119539, filed on Sep. 21, 2022, in the Korean Intellectual Property Office, the entire disclosure of which is incorporated by reference herein.

### BACKGROUND

### 1. Field

Aspects of one or more embodiments of the present disclosure relate to a display apparatus and a method of manufacturing the display apparatus.

### 2. Description of the Related Art

Display apparatuses display data visually. Display apparatuses are used as displays of compact products such as mobile phones, or large-sized products such as televisions.

A display apparatus includes a plurality of pixels that receive an electrical signal, and emit light to display an image. Each pixel includes a display element. For example, an organic light-emitting display apparatus includes an organic light-emitting diode (OLED) as the display element.

The above information disclosed in this Background section is for enhancement of understanding of the background of the present disclosure, and therefore, it may contain information that does not constitute prior art.

### SUMMARY

In general, a display apparatus includes thin-film transistors and a capacitor to control light emission of the pixels. The thin-film transistors include a semiconductor layer including, for example, polysilicon, and a gate electrode at least partially overlapping with the semiconductor layer. The semiconductor layer includes a channel region, and source/drain regions on opposite sides of a semiconductor region and doped with a dopant. As high-quality display apparatuses may be implemented according to the characteristics of the thin-film transistors, research into the improvement of the quality of the thin-film transistors is currently being actively conducted.

One or more embodiments are directed to a high-quality display apparatus having improved product reliability, by preventing or substantially preventing over-etching in an etching process, and a manufacturing method thereof.

However, the present disclosure is not limited to the above aspects and features. Additional aspects and features will be set forth, in part, in the description that follows, and in part, will be apparent from the description, or may be learned by practicing one or more of the presented embodiments of the present disclosure.

According to one or more embodiments of the present disclosure, a display apparatus includes: a substrate; a buffer layer on the substrate; a first semiconductor layer on the buffer layer; a first gate insulating layer on the first semiconductor layer; a first metal layer on the first gate insulating layer; a second gate insulating layer on the first metal layer; a second metal layer on the second gate insulating layer; a first interlayer insulating layer on the second metal layer; and a first dopant doped in at least one of the second gate insulating layer or the first interlayer insulating layer.

In an embodiment, the first dopant may include fluorine.

In an embodiment, each of the second gate insulating layer and the first interlayer insulating layer may include at least one of silicon oxide, silicon nitride, or silicon oxynitride.

In an embodiment, the display apparatus may further include: a second semiconductor layer and a third metal layer on the first interlayer insulating layer; a second interlayer insulating layer on the second semiconductor layer and the third metal layer; and a fourth metal layer on the second interlayer insulating layer.

In an embodiment, the fourth metal layer may be electrically connected to the first semiconductor layer through a first contact hole penetrating the first gate insulating layer, the second gate insulating layer, the first interlayer insulating layer, and the second interlayer insulating layer; the fourth metal layer may be electrically connected to the second semiconductor layer through a second contact hole penetrating the second interlayer insulating layer; and a depth of the first contact hole may be greater than a depth of the second contact hole.

In an embodiment, the fourth metal layer may be electrically connected to the first metal layer through a third contact hole penetrating the second gate insulating layer, the first interlayer insulating layer, and the second interlayer insulating layer; the fourth metal layer may be electrically connected to the second semiconductor layer through a fourth contact hole penetrating the second interlayer insulating layer; and a depth of the third contact hole may be greater than a depth of the fourth contact hole.

In an embodiment, each of the second gate insulating layer and the first interlayer insulating layer may include the first dopant, and the second gate insulating layer and the first interlayer insulating layer may be located between the first metal layer and the second semiconductor layer.

In an embodiment, a thickness of the first interlayer insulating layer may be greater than a thickness of the second gate insulating layer, and a first distance from a maximum concentration point of the first dopant to an upper surface of the first interlayer insulating layer in a thickness direction of the first interlayer insulating layer may be greater than a second distance from a maximum concentration point of the first dopant to an upper surface of the second gate insulating layer in a thickness direction of the second gate insulating layer.

In an embodiment, the display apparatus may further include a fifth metal layer on the first gate insulating layer, the fifth metal layer may be electrically connected to the second metal layer through a fifth contact hole penetrating the first interlayer insulating layer, the fifth metal layer may be electrically connected to the first semiconductor layer through a sixth contact hole penetrating the first gate insulating layer, the second gate insulating layer, the first interlayer insulating layer, and a depth of the sixth contact hole may be greater than a depth of the fifth contact hole.

In an embodiment, the second gate insulating layer may include the first dopant, and may be located between the first metal layer and the second metal layer.

According to one or more embodiments of the present disclosure a display apparatus includes: a substrate; a first silicon-based transistor on the substrate, and including a first semiconductor layer including a silicon-based semiconductor, and a first gate electrode overlapping with the first semiconductor layer; at least one insulating layer on the first gate electrode; a first oxide-based transistor on the at least one insulating layer, and including a second semiconductor layer including an oxide-based semiconductor; and a first connection electrode connecting the first semiconductor layer of the first silicon-based transistor to the second semiconductor layer of the first oxide-based transistor. The first connection electrode is electrically connected to the first semiconductor layer through a first contact hole, and the first connection electrode is electrically connected to the second semiconductor layer through a second contact hole, the first contact hole having a depth different from a depth of the second contact hole. An insulating layer from among the at least one insulating layer is located between the first gate electrode and the second semiconductor layer, and includes an inorganic insulating material doped with a first dopant.

In an embodiment, the first dopant may include fluorine.

In an embodiment, the at least one insulating layer may include: a first gate insulating layer on the first semiconductor layer of the first silicon-based transistor; a second gate insulating layer on the first gate electrode of the first silicon-based transistor; and a first interlayer insulating layer on the second gate insulating layer. The first contact hole may penetrate the first gate insulating layer, the second gate insulating layer, and the first interlayer insulating layer, and the second contact hole may penetrate the first interlayer insulating layer.

In an embodiment, the display apparatus may further include: a first node connection electrode connecting the first gate electrode of the first silicon-based transistor to the second semiconductor layer of the first oxide-based transistor. A depth of a third contact hole for electrically connecting the first node connection electrode to the first gate electrode may be different from a depth of a fourth contact hole for electrically connecting the first node connection electrode to the second semiconductor layer.

In an embodiment, the third contact hole may penetrate the second gate insulating layer and the first interlayer insulating layer, and the fourth contact hole may penetrate the first interlayer insulating layer.

In an embodiment, each of the second gate insulating layer and the first interlayer insulating layer may include the first dopant, and may be located between the first gate electrode and the second semiconductor layer.

According to one or more embodiments of the present disclosure, a method of manufacturing a display apparatus, includes: forming a buffer layer on a substrate; forming a first semiconductor layer on the buffer layer; forming a first gate insulating layer on the first semiconductor layer; forming a first metal layer on the first gate insulating layer; forming a second gate insulating layer on the first metal layer; and implanting a first dopant into the second gate insulating layer at a first acceleration voltage.

In an embodiment, the first dopant may include fluorine.

In an embodiment, the method may further include: forming a second metal layer on the second gate insulating layer; forming a first interlayer insulating layer to cover the second metal layer; and implanting the first dopant into the first interlayer insulating layer at a second acceleration voltage.

In an embodiment, the second acceleration voltage may have a greater value than the first acceleration voltage.

In an embodiment, each of a dose amount of the first dopant implanted into the second gate insulating layer and a dose amount of the first dopant implanted into the first interlayer insulating layer may have a value in a range from 1.0×E¹⁴ atoms/cm² to 1.0×E¹⁵ atoms/cm².

In an embodiment, the first dopant may be implanted into at least a portion of each of the second gate insulating layer and the first interlayer insulating layer by ion implantation or plasma treatment.

In an embodiment, the method may further include forming a plurality of contact holes in the second gate insulating layer and the first interlayer insulating layer, and the forming of the plurality of contact holes may include dry-etching the second gate insulating layer and the first interlayer insulating layer using at least one of CF₄ gas, CHF₃ gas, C₂HF₅ gas, or CH₂F₂ gas.

In an embodiment, a process time of a dry-etching process of the second gate insulating layer and the first gate insulating layer may be decreased by the first dopant compared to when the first dopant is not implanted.

In an embodiment, the method may further include: forming a second semiconductor layer and a third metal layer on the first interlayer insulating layer; forming a second interlayer insulating layer on the second semiconductor layer and the third metal layer; and forming a fourth metal layer on the second interlayer insulating layer.

In an embodiment, the forming of the plurality of contact holes may include: forming a first contact hole penetrating the first gate insulating layer, the second gate insulating layer, the first interlayer insulating layer, and the second interlayer insulating layer; and forming a second contact hole penetrating the second interlayer insulating layer. The fourth metal layer may be electrically connected to the first semiconductor layer through the first contact hole, and the fourth metal layer may be electrically connected to the second semiconductor layer through the second contact hole.

In an embodiment, the forming of the plurality of contact holes may include: forming a third contact hole penetrating the second gate insulating layer, the first interlayer insulating layer, and the second interlayer insulating layer; and forming a fourth contact hole penetrating the second interlayer insulating layer. The fourth metal layer may be electrically connected to the first metal layer through the third contact hole, and the fourth metal layer may be electrically connected to the second semiconductor layer through the fourth contact hole.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a schematic plan view of a display apparatus according to an embodiment;

FIG. 2A is an equivalent circuit diagram illustrating a pixel circuit and a light-emitting diode electrically connected to the pixel circuit, which are included in a display apparatus according to an embodiment;

FIG. 2B is an equivalent circuit diagram illustrating a pixel circuit and a light-emitting diode electrically connected to the pixel circuit, which are included in a display apparatus according to an embodiment;

FIG. 3 is a schematic plan view of a portion of a sub-pixel circuit area of a display area of a display apparatus according to an embodiment;

FIG. 4 is a schematic cross-sectional view of a thin-film transistor substrate according to an embodiment;

FIGS. 5A-5F are schematic cross-sectional views sequentially illustrating various processes of a method of manufacturing a thin-film transistor substrate, according to an embodiment;

FIG. 6 is a schematic cross-sectional view of a display apparatus according to an embodiment;

FIG. 7 is a graph illustrating a comparison of etch rates according to a doping concentration in a display apparatus, according to an embodiment;

FIGS. 8A-8D are graphs illustrating a position in a display apparatus where a dopant is implanted, according to an embodiment; and

FIG. 9 is a schematic cross-sectional view of a thin-film transistor substrate according to an embodiment.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

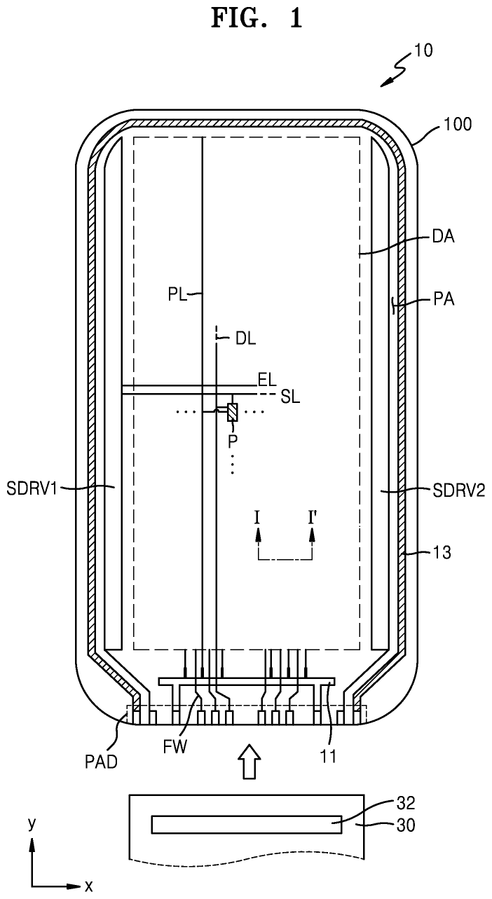

FIG. 1 is a schematic plan view of a display apparatus according to an embodiment.

Referring to FIG. 1, various components included in a display apparatus 10 may be disposed on a substrate 100. The substrate 100 may include a display area DA, and a peripheral area PA surrounding (e.g., around a periphery of) the display area DA. The display area DA may be covered with an encapsulation member to be protected from external air and/or moisture.

Sub-pixels P are arranged at (e.g., in or on) the display area DA of the substrate 100. The sub-pixels P may each emit light from a display element, such as a light-emitting diode, to display an image. Each light-emitting diode may emit, for example, red, green, or blue light.

Each light-emitting diode may be electrically connected to a corresponding sub-pixel circuit, and each sub-pixel circuit may include transistors and a storage capacitor. Each sub-pixel circuit may be electrically connected to peripheral circuits arranged at (e.g., in or on) the peripheral area PA. The peripheral circuits arranged at (e.g., in or on) the peripheral area PA may include a first scan driving circuit SDRV1, a second scan driving circuit SDRV2, a terminal portion PAD, a driving voltage supply line 11, and a common voltage supply line 13.

The first scan driving circuit SDRV1 may apply a scan signal to each of the sub-pixel circuits corresponding to the sub-pixels P through a corresponding scan line SL. The first scan driving circuit SDRV1 may apply an emission control signal to each sub-pixel circuit through a corresponding emission control line EL. The second scan driving circuit SDRV2 may be located opposite to the first scan driving circuit SDRV1 with respect to the display area DA, and may be parallel to or substantially parallel to the first scan driving circuit SDRV1. Some of the sub-pixel circuits may be electrically connected to the first scan driving circuit SDRV1, and others of the sub-pixel circuits may be electrically connected to the second scan driving circuit SDRV2. In some embodiments, the second scan driving circuit SDRV2 may be omitted as needed or desired.

The terminal portion PAD may be arranged at one side of the substrate 100. The terminal portion PAD may not be covered by an insulating layer, and may be exposed to be connected to a display circuit board 30. A display driver 32 may be disposed on the display circuit board 30.

The display driver 32 may generate a control signal to be transmitted to the first scan driving circuit SDRV1 and the second scan driving circuit SDRV2. The display driver 32 may generate a data signal, and the data signal may be transmitted to the sub-pixel circuits of the sub-pixels P through a fan-out wire FW and a data line DL connected to the fan-out wire FW.

The display driver 32 may supply a driving voltage ELVDD to the driving voltage supply line 11, and may supply a common voltage ELVSS to the common voltage supply line 13. The driving voltage ELVDD may be applied to the sub-pixel circuits of the sub-pixel P through a driving voltage line PL connected to the driving voltage supply line 11. The common voltage ELVSS may be applied to an opposite electrode of a display element through the common voltage supply line 13.

The driving voltage supply line 11 may extend in an x-direction at the lower side of the display area DA. The common voltage supply line 13 may have a loop shape with one side open, and may partially surround (e.g., around a periphery of) the display area DA.

The display apparatus 10 illustrated in FIG. 1 is a device for displaying a moving image and/or a still image. For example, the display apparatus 10 may include a mobile phone, a smart phone, a tablet personal computer (PC), a mobile communication terminal, an electronic notebook, an e-book, a portable multimedia player (PMP), a navigation device, and/or an ultra-mobile PC (UMPC). As another example, the display apparatus 10 may be used as a display screen of various suitable products, such as a television, a notebook computer, a monitor, a billboard, and/or an Internet of Things (IoT) device. As another example, the display apparatus 1 according to an embodiment may be used in a wearable device, such as a smart watch, a watch phone, a glasses-type display, and/or a head mounted display (HMD). As another example, the display apparatus 10 according to an embodiment may be used as a display for an instrumental panel of a vehicle, a center information display (CID) disposed on a center fascia or a dashboard of a vehicle, a rear-view mirror display instead of a side mirror of a vehicle, and/or a display located on the back of the front seat of the vehicle as entertainment for a passenger in the rear seat of the vehicle.

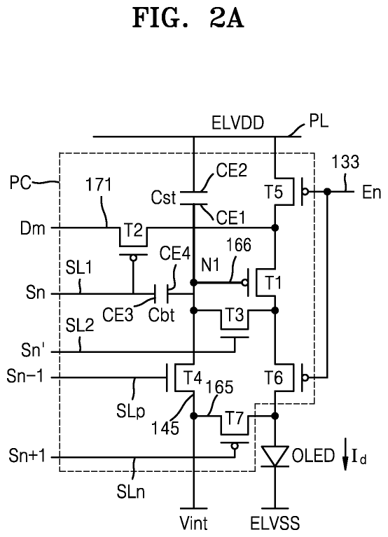

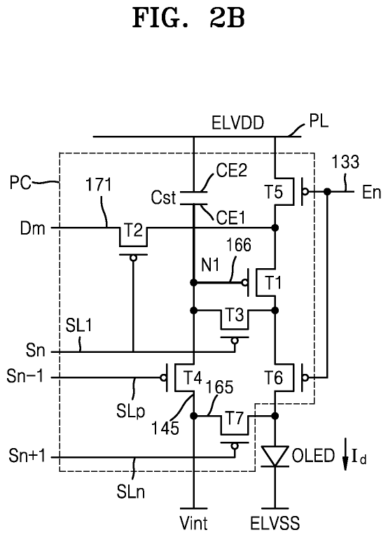

FIG. 2A is an equivalent circuit diagram illustrating a pixel circuit and a light-emitting diode electrically connected to the pixel circuit, which are included in a display apparatus according to an embodiment.

An emission layer of a light-emitting diode may include an organic material, an inorganic material, quantum dots, and/or the like. For example, in an embodiment, as illustrated in FIG. 2, the light-emitting diode may be an organic light-emitting diode (OLED), but the present disclosure is not limited thereto. While FIG. 2A illustrates that the light-emitting diode includes an organic light-emitting diode OLED, in other embodiments, the display apparatus 10 may include, for example, an inorganic light-emitting diode or a quantum dot light-emitting diode, instead of the organic light-emitting diode OLED.

The organic light-emitting diode OLED may be electrically connected to a sub-pixel circuit PC. Referring to FIG. 2A, the sub-pixel circuit PC may include first to seventh transistors T1, T2, T3, T4, T5, T6, and T7, a storage capacitor Cst, and a boost capacitor Cbt. In some embodiments, the sub-pixel circuit PC may not include the boost capacitor Cbt. Hereinafter, for convenience, the sub-pixel circuit PC including the boost capacitor Cbt is described in more detail.

Some of the first to seventh transistors T1, T2, T3, T4, T5, T6, and T7 may be n-channel metal oxide semiconductor field effect transistors (MOSFET) (NMOS transistors), and others may be p-channel MOSFET (PMOS transistors). For example, the third and fourth transistors T3 and T4 may be NMOS transistors, and the others may be PMOS transistors. In another embodiment, the third, fourth, and seventh transistors T3, T4, and T7 may be NMOS transistors, and the others may be PMOS transistors. As another example, one of the first to seventh transistors T1, T2, T3, T4, T5, T6, and T7 may be an NMOS transistor, and the others may be PMOS transistors.

The first to seventh transistors T1, T2, T3, T4, T5, T6, and T7, the storage capacitor Cst, and the boost capacitor Cbt may be connected to a signal line. The signal line may include a first scan line SL1 configured to transmit a first scan signal Sn, a second scan line SL2 configured to transmit a second scan signal Sn′, a previous scan line SLp configured to transmit a previous scan signal Sn−1, an emission control line 133 configured to transmit an emission control signal En, a next scan line SLn configured to transmit a subsequent scan signal Sn+1, and a data line 171 crossing the first scan line SL1, and configured to transmit a data signal Dm, where n and m are natural numbers.

The driving voltage line PL may be configured to transfer the driving voltage ELVDD to the first transistor T1. First and second initialization voltage lines 145 and 165 may be configured to transfer an initialization voltage Vint.

The first transistor T1 may include a driving transistor. A first gate electrode (e.g., a first control electrode) of the first transistor T1 may be connected to the storage capacitor Cst. A first electrode of the first transistor T1 may be electrically connected to the driving voltage line PL via the fifth transistor T5, and a second electrode of the first transistor T1 may be electrically connected to a pixel electrode of the organic light-emitting diode OLED via the sixth transistor T6. One of the first electrode and the second electrode of the first transistor T1 may be a source electrode, and the other may be a drain electrode. The first transistor T1 may receive the data signal Dm according to a switching operation of the second transistor T2, and may supply a driving current Id to the organic light-emitting diode OLED.

The second transistor T2 may include a switching transistor. A second gate electrode (e.g., a second control electrode) of the second transistor T2 may be connected to the first scan line SL1, and a first electrode of the second transistor T2 may be connected to the data line 171. A second electrode of the second transistor T2 may be connected to the first electrode of the first transistor T1, and may be electrically connected to the driving voltage line PL via the fifth transistor T5. One of the first electrode and the second electrode of the second transistor T2 may be a source electrode, and the other may be a drain electrode. The second transistor T2 is turned on according to the first scan signal Sn received through the first scan line SL1, to perform a switching operation of transmitting the data signal Dm transmitted through the data line 171 to the first electrode of the first transistor T1.

The third transistor T3 may include a compensation transistor to compensate for a threshold voltage of the first transistor T1. A third gate electrode (e.g., a compensation control electrode) of the third transistor T3 is connected to the second scan line SL2. A first electrode of the third transistor T3 is connected to a lower electrode CE1 of the storage capacitor Cst, and the first gate electrode of the first transistor T1 through a node connection electrode 166. The first electrode of the third transistor T3 may be connected to the fourth transistor T4. A second electrode of the third transistor T3 is connected to the second electrode of the first transistor T1, and is electrically connected to the pixel electrode of the organic light-emitting diode OLED via the sixth transistor T6. One of the first electrode and the second electrode of the third transistor T3 may be a source electrode, and the other may be a drain electrode.

The third transistor T3 is turned on according to the second scan signal Sn′ received through the second scan line SL2, to electrically connect the first gate electrode and the second electrode of the first transistor T1 to each other to diode-connect the first transistor T1.

The fourth transistor T4 may include a first initialization transistor that initializes the first gate electrode of the first transistor T1. A fourth gate electrode (e.g., a fourth control electrode) of the fourth transistor T4 is connected to the previous scan line SLp. A first electrode of the fourth transistor T4 is connected to the first initialization voltage line 145. A second electrode of the fourth transistor T4 may be connected to the lower electrode CE1 of the storage capacitor Cst, the first electrode of the third transistor T3, and the first gate electrode of the first transistor T1. One of the first electrode and the second electrode of the fourth transistor T4 may be a source electrode, and the other may be a drain electrode. The fourth transistor T4 may be turned on according to the previous scan signal Sn−1 received through the previous scan line SLp, to perform an initialization operation of transmitting the initialization voltage Vint to the first gate electrode of the first transistor T1, and initializing a voltage of the first gate electrode of the first transistor T1.

The fifth transistor T5 may include an operation control transistor. A fifth gate electrode (e.g., a fifth control electrode) of the fifth transistor T5 is connected to the emission control line 133, and a first electrode of the fifth transistor T5 is connected to the driving voltage line PL. A second electrode of the fifth transistor T5 is connected to the first electrode of the first transistor T1 and the second electrode of the second transistor T2. One of the first electrode and the second electrode of the fifth transistor T5 may be a source electrode, and the other may be a drain electrode.

The sixth transistor T6 may include an emission control transistor. A sixth gate electrode (e.g., a sixth control electrode) of the sixth transistor T6 is connected to the emission control line 133. A first electrode of the sixth transistor T6 is connected to the second electrode of the first transistor T1 and the second electrode of the third transistor T3. A second electrode of the sixth transistor T6 is electrically connected to a second electrode of the seventh transistor T7 and the pixel electrode of the organic light-emitting diode OLED. One of the first electrode and the second electrode of the sixth transistor T6 may be a source electrode, and the other may be a drain electrode.

The fifth transistor T5 and the sixth transistor T6 may be concurrently (e.g., simultaneously or substantially simultaneously) turned on with each other according to the emission control signal En received through the emission control line 133, and the driving voltage ELVDD may be transmitted to the organic light-emitting diode OLED so that the driving current Id flows through the organic light-emitting diode OLED.

The seventh transistor T7 may include a second initialization transistor that initializes the pixel electrode of the organic light-emitting diode OLED. A seventh gate electrode (e.g., a seventh control electrode) of the seventh transistor T7 is connected to the next scan line SLn. A first electrode of the seventh transistor T7 is connected to the second initialization voltage line 165. The second electrode of the seventh transistor T7 is connected to the second electrode of the sixth transistor T6 and the pixel electrode of the organic light-emitting diode OLED. After receiving a scan signal through the next scan line SLn, the seventh transistor T7 may be turned on according to the subsequent scan signal Sn+1 to initialize the pixel electrode of the organic light-emitting diode OLED. Although FIG. 2A illustrates that the seventh transistor T7 is connected to the next scan line SLn, the present disclosure is not limited thereto, and the seventh transistor T7 may be connected to the emission control line 133 to be driven according to the emission control signal En.

The storage capacitor Cst includes the lower electrode CE1 and an upper electrode CE2. The lower electrode CE1 of the storage capacitor Cst is connected to the first gate electrode of the first transistor T1, and the upper electrode CE2 of the storage capacitor Cst is connected to the driving voltage line PL. The storage capacitor Cst may store a charge corresponding to a difference between a voltage of the first gate electrode of the first transistor T1 and the driving voltage ELVDD.

The boost capacitor Cbt includes a third electrode CE3 and a fourth electrode CE4. The third electrode CE3 may be connected to the second gate electrode of the second transistor T2 and the first scan line SL1. The fourth electrode CE4 may be connected to the first electrode of the third transistor T3 and the node connection electrode 166. The boost capacitor Cbt may increase a voltage of the first node N1 when the first scan signal Sn supplied to the first scan line SL1 has a turn off level, and when the voltage of the first node N1 increases, the boost capacitor Cbt may clearly express a black gradation (e.g., a black grayscale level or value).

The first node N1 may be a region where the first gate electrode of the first transistor T1, the first electrode of the third transistor T3, the second electrode of the fourth transistor T4, and the fourth electrode CE4 of the boost capacitor Cbt are connected to one another.

In an embodiment, as illustrated in FIG. 2A, the third and fourth transistors T3 and T4 are NMOS transistors, and the first, second, and fifth to seventh transistors T1, T2, T5, T6, and T7 are PMOS transistors. The first transistor T1, which directly affects the brightness of a display apparatus, includes a semiconductor layer including polycrystalline silicon having high reliability, and accordingly, a high-resolution display apparatus may be implemented.

FIG. 2B is an equivalent circuit diagram illustrating a pixel circuit and a light-emitting diode electrically connected to the pixel circuit, which are included in a display apparatus according to an embodiment.

As described above with reference to FIG. 2A, the sub-pixel circuit PC may include the third transistor T3 and the fourth transistor T4 that are NMOS transistors, and the first, second, and fifth to seventh transistors T1, T2, T5, T6, and T7 that are PMOS transistors. However, the present disclosure is not limited thereto. In another embodiment, as illustrated in FIG. 2B, all of the first to seventh transistors T1, T2, T3, T4, T5, T6, and T7 may be PMOS transistors, and the booster capacitor Cbt may be omitted.

Referring to FIG. 2B, the second transistor T2 and the third transistor T3 may be connected to the same scan line, for example, such as the first scan line SL1. The connection structures of the other components illustrated in FIG. 2B may be the same or substantially the same as those described above with reference to FIG. 2A, and thus, redundant description thereof may not be repeated.

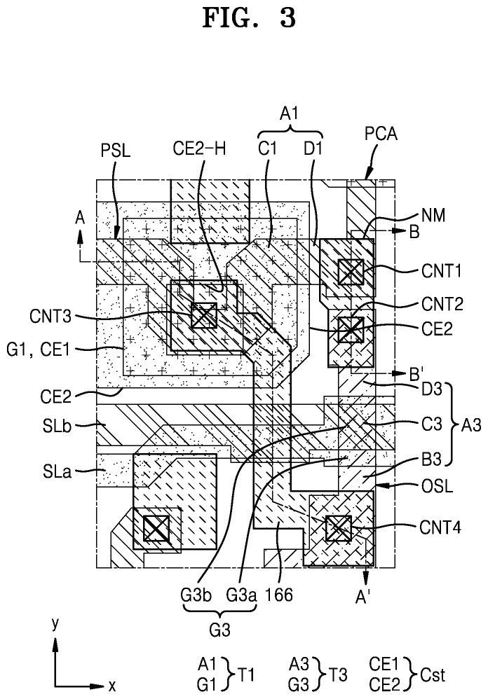

FIG. 3 is a schematic plan view of a portion of a sub-pixel circuit area of a display area of a display apparatus according to an embodiment.

Referring to FIG. 3, the sub-pixel circuits described above with reference to FIG. 2A or 2B may be arranged to form rows and columns at (e.g., in or on) the display area DA of the display apparatus 10 described above with reference to FIG. 1. An area in which each sub-pixel circuit is disposed may be referred to as a sub-pixel circuit area PCA, which may be arranged at (e.g., in or on) the display area of the display apparatus 10.

FIG. 3 illustrates a portion of the sub-pixel circuit area PCA, such as a first semiconductor layer A1 and a first gate electrode G1 of the first transistor T1, and a third semiconductor layer A3 of the third transistor T3, which are included in the sub-pixel circuit described above with reference to FIG. 2A.

In the sub-pixel circuit area PCA, a plurality of gates lines (which may be scan lines) SLa and SLb may each extend in a first direction (e.g., the x-direction), and may be spaced apart from each other. The data line DL and the power voltage line PL (e.g., see FIG. 1) may each extend in a second direction (e.g., the y-direction), and may be spaced apart from each other.

The first transistor T1 may be a transistor (hereinafter, referred to as a silicon-based transistor) including a silicon-based semiconductor layer, and may be formed along a silicon semiconductor pattern PSL. In other words, the silicon semiconductor pattern PSL may include the first semiconductor layer A1. In addition to the first semiconductor layer A1, the silicon semiconductor pattern PSL may include a second semiconductor layer of a second transistor (e.g., T2), a fifth semiconductor layer of a fifth transistor (e.g., T5), and a sixth semiconductor layer of a sixth transistor (e.g., T6), which may be connected to one another and formed integrally with each other as a single body.

The third transistor T3 may be a transistor (hereinafter, referred to as an oxide-based transistor) including an oxide-based semiconductor layer, and may be formed along an oxide semiconductor pattern OSL. In other words, the oxide semiconductor pattern OSL may be curved in various suitable shapes, and the oxide semiconductor pattern OSL may include the third semiconductor layer A3. The oxide semiconductor pattern OSL may further include a fourth semiconductor layer of a fourth transistor (e.g., T4).

The first semiconductor layer A1 may include a first channel region C1, and a first region (not shown) and a second region D1 arranged on opposite sides of the first channel region C1. The first region and the second region D1 of the first semiconductor layer A1 are regions doped with impurities, and have higher electrical conductivity than that of the first channel region C1. One of the first region and the second region D1 may be a source region, and the other may be a drain region.

The first gate electrode G1 of the first transistor T1 and the lower electrode CE1 of the storage capacitor Cst may be disposed on the first semiconductor layer A1.

The first gate electrode G1 may have an isolated shape in a plan view, and the first gate electrode G1 may include the lower electrode CE1 of the storage capacitor Cst. In other words, the first gate electrode G1 and the lower electrode CE1 of the storage capacitor Cst may be integrally formed with each other as a single body, and thus, in other words, the lower electrode CE1 of the storage capacitor Cst includes the first gate electrode G1. The first gate electrode G1 and the lower electrode CE1 of the storage capacitor Cst may be formed to entirely cover the first channel region C1 of the first semiconductor layer A1.

The upper electrode CE2 of the storage capacitor Cst and a lower gate line SLa may be disposed on the first gate electrode G1.

The upper electrode CE2 of the storage capacitor Cst may overlap with the lower electrode CE1 of the storage capacitor Cst, and may include a hole CE2-H exposing a portion of the lower electrode CE1 of the storage capacitor Cst. The hole CE2-H may have a structure that is entirely surrounded (e.g., around a periphery thereof) in a plan view by a material portion constituting the upper electrode CE2 of the storage capacitor Cst. The upper electrode CE2 of the storage capacitor Cst may have a donut-like shape in a plan view.

The lower gate line SLa may extend in the x-direction. The lower gate line SLa may include a lower gate electrode G3a, which may be a portion of the third gate electrode G3 of the third transistor T3. The upper electrode CE2 of the storage capacitor Cst and the lower gate line SLa may include the same material as each other, and may be disposed at (e.g., in or on) the same layer as each other.

The oxide semiconductor pattern OSL may include the third semiconductor layer A3, and may be disposed on an insulating layer, which is on the upper electrode CE2 of the storage capacitor Cst and the lower gate line SLa. The oxide semiconductor pattern OSL may include an oxide-based semiconductor material, for example, such as Zn oxide, In—Zn oxide, Ga—In—Zn oxide, In—Ga—O oxide, or the like. In some embodiments, the oxide semiconductor pattern OSL may include an In—Ga—Zn—O (IGZO) semiconductor, an In—Sn—Zn—O (ITZO) semiconductor, an In—Ga—O (IGO) semiconductor, or an In—Ga—Sn—Zn—O (IGTZO) semiconductor, which are ZnO containing a metal, such as indium (In), gallium (Ga), tin (Sn), and/or the like.

The third semiconductor layer A3 may include a third channel region C3, and a first region B3 and a second region D3 arranged on opposite sides of the third channel region C3. The first region B3 and the second region D3 of the third semiconductor layer A3 are conductive regions, and have higher electrical conductivity than that of the third channel region C3. One of the first region B3 and the second region D3 may be a source region, and the other may be a drain region.

An upper gate line SLb may be formed on the third semiconductor layer A3, with an insulating layer therebetween. At least a portion of the upper gate line SLb may overlap with the lower gate line SLa, with the oxide semiconductor pattern OSL therebetween. The upper gate line SLb may include an upper gate electrode G3b, which may be a portion of the third gate electrode G3 of the third transistor T3.

A connection electrode NM and the node connection electrode 166 may be formed on the upper gate line SLb, with an insulating layer therebetween. The connection electrode NM and the node connection electrode 166 may include the same material as each other, and may be disposed at (e.g., in or on) the same layer as each other.

The connection electrode NM may electrically connect the first semiconductor layer A1 of the silicon semiconductor pattern PSL to the third semiconductor layer A3 of the oxide semiconductor pattern OSL. For example, the connection electrode NM may be connected to the second region D1 that is a portion of the first semiconductor layer A1 through a first contact hole CNT1, and may be connected to the second region D3 of the third semiconductor layer A3 through a second contact hole CNT2.

The node connection electrode 166 may electrically connect the first gate electrode G1 of the first transistor T1 to the first region B3 of the third semiconductor layer A3. For example, the node connection electrode 166 may be connected to the first gate electrode G1 through a third contact hole CNT3, and may be connected to the first region B3, which is a portion of the third semiconductor layer A3, through a fourth contact hole CNT4.

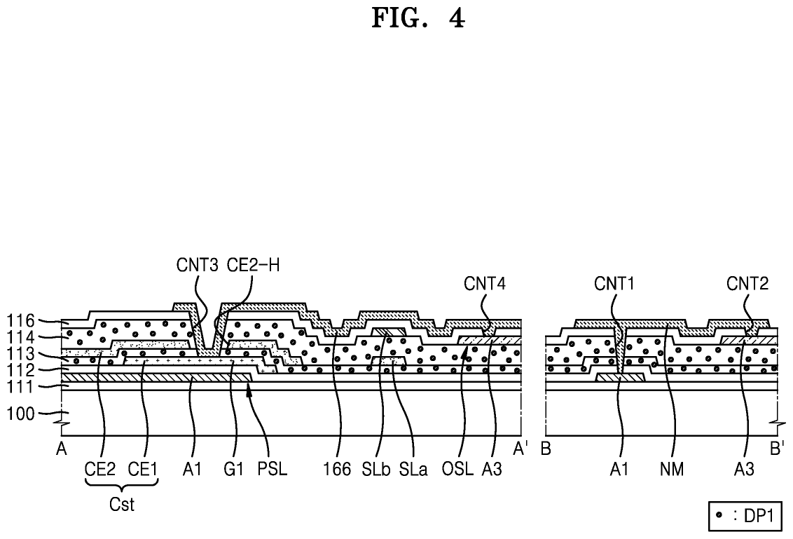

FIG. 4 is a schematic cross-sectional view of a thin-film transistor substrate according to an embodiment. FIG. 4 corresponds to a cross-section of the display apparatus taken along the lines A-A′ and B-B′ illustrated in FIG. 3. Hereinafter, a stacking order of the thin-film transistor substrate may be described in more detail with reference to FIG. 4.

Referring to FIG. 4, the substrate 100 may include a glass material or a polymer resin. For example, the polymer resin may include polyethersulfone, polyacrylate, polyether imide, polyethylene naphthalate, polyethylene terephthalate, polyphenylene sulfide, polyarylate, polyimide, polycarbonate, cellulose acetate propionate, or the like. The substrate 100 including the polymer resin may be flexible, rollable, or bendable. The substrate 100 may have a multi-layered structure including the polymer resin and an inorganic layer.

A buffer layer 111 may be disposed on an upper surface of the substrate 100. The buffer layer 111 may prevent or substantially prevent impurities from penetrating into a semiconductor layer of a transistor. The buffer layer 111 may include an inorganic insulating material, such as silicon nitride, silicon oxynitride, and/or silicon oxide, and may be a single layer or multiple layers including one or more of the above-described inorganic insulating materials.

Semiconductor layers of silicon-based transistors may be disposed on the buffer layer 111. For example, FIG. 4 illustrates that the first semiconductor layer A1 of the first transistor T1 corresponding to a portion of the silicon semiconductor pattern PSL is disposed on the buffer layer 111. The first semiconductor layer A1 may include the first channel region C1, and the impurity-doped impurity regions arranged on opposite sides of the first channel region C1. The first semiconductor layer A1 may include a silicon-based semiconductor material, for example, such as polysilicon.

A first gate insulating layer 112 may be disposed on the silicon semiconductor pattern PSL, or in other words, on the first semiconductor layer A1. The first gate insulating layer 112 may include an inorganic insulating layer including an inorganic insulating material, such as silicon oxide, silicon nitride, and/or silicon oxynitride, and may have a single-layer or multi-layered structure including one or more of the above-described materials.

The first gate electrode G1 of the first transistor T1 and the lower electrode CE1 of the storage capacitor Cst may be disposed on the first gate insulating layer 112. The first gate electrode G1 and the lower electrode CE1 of the storage capacitor Cst may be referred to as a first metal layer in the present disclosure. FIG. 4 illustrates that the first gate electrode G1 is integrally formed as a single body with the lower electrode CE1 of the storage capacitor Cst. In other words, the first gate electrode G1 may perform a function as the lower electrode CE1 of the storage capacitor Cst, and/or the lower electrode CE1 of the storage capacitor Cst may perform a function as the first gate electrode G1.

The first gate electrode G1 and the lower electrode CE1 of the storage capacitor Cst may include, for example, aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may include a single layer or multiple layers including one or more of the above-described materials.

A second gate insulating layer 113 may be disposed on the first gate electrode G1 and/or the lower electrode CE1 of the storage capacitor Cst. In an embodiment, the second gate insulating layer 113 may include an inorganic insulating material including a first dopant DP1. The second gate insulating layer 113 may include silicon oxide including the first dopant DP1, silicon nitride including the first dopant DP1, and/or silicon oxynitride including the first dopant DP1, and may have a single-layer or multi-layered structure including one or more of the above-described materials. The first dopant DP1 may include fluorine.

The upper electrode CE2 of the storage capacitor Cst and the lower gate line SLa may be disposed on the second gate insulating layer 113. The upper electrode CE2 of the storage capacitor Cst and the lower gate line SLa may be referred to as a second metal layer in the present disclosure. The upper electrode CE2 of the storage capacitor Cst may include, for example, aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may include a single layer or multiple layers including one or more of the above-described materials. The upper electrode CE2 of the storage capacitor Cst may overlap with the first gate electrode G1 and/or the lower electrode CE1 of the storage capacitor Cst.

The upper electrode CE2 of the storage capacitor Cst may include the hole CE2-H penetrating therethrough, such that the node connection electrode 166, which is for electrically connecting the first gate electrode G1 of the first transistor T1 to the third transistor T3, may be connected to the first gate electrode G1.

The lower gate line SLa may include the same material as that of the upper electrode CE2 of the storage capacitor Cst, and be disposed at (e.g., in or on) the same layer as that of the upper electrode CE2. As described above with reference to FIG. 3, the third gate electrode G3 of the third transistor T3 may include the upper gate electrode G3b and the lower gate electrode G3a, and a portion of the lower gate line SLa may include the lower gate electrode G3a of the third transistor T3.

A first interlayer insulating layer 114 may be disposed on the upper electrode CE2 of the storage capacitor Cst and the lower gate line SLa. In an embodiment, the first interlayer insulating layer 114 may include an inorganic insulating material including the first dopant DP1. For example, the first interlayer insulating layer 114 may include the inorganic insulating material, such as silicon oxide including the first dopant DP1, silicon nitride including the first dopant DP1, and/or silicon oxynitride including the first dopant DP1, and may have a single-layer or multi-layered structure including one or more of the above-described materials. The first dopant DP1 may include fluorine.

Oxide semiconductor layers may be disposed on the first interlayer insulating layer 114. For example, FIG. 4 illustrates the third semiconductor layer A3 of the third transistor T3 corresponding to a portion of the oxide semiconductor pattern OSL. The third semiconductor layer A3 may include the third channel region C3, and conductive regions arranged on opposite sides of the third channel region C3.

The third semiconductor layer A3 may include an oxide-based semiconductor material. For example, the third semiconductor layer A3 may include, for example, a Zn-based material, such as Zn oxide, In—Zn oxide, Ga—In—Zn oxide, In—Ga—O oxide, or the like. In some embodiments, the third semiconductor layer A3 may include an IGZO semiconductor, an ITZO semiconductor, an IGO semiconductor, or an IGTZO semiconductor, which are ZnO containing a metal, such as indium (In), gallium (Ga), tin (Sn), and/or the like.

The upper gate line SLb may be disposed on the first interlayer insulating layer 114. The upper gate line SLb may be referred to as a third metal layer in the present disclosure. A portion of the upper gate line SLb may include the upper gate electrode G3b of the third transistor T3, as described above with reference to FIG. 3. The upper gate electrode G3b of the third transistor T3 corresponding to the portion of the upper gate line SLb may be disposed on the third semiconductor layer A3, with a third gate insulating layer therebetween. In other words, the third gate insulating layer may be locally disposed only between the upper gate electrode G3b of the third transistor T3 and the third semiconductor layer A3, and another portion of the upper gate line SLb may be disposed on the first interlayer insulating layer 114 as illustrated in FIG. 4. In another embodiment, the third gate insulating layer may completely or substantially completely cover the substrate 100, like the first interlayer insulating layer 114. In this case, the other portion of the upper gate line SLb may also be disposed on the third gate insulating layer.

The upper gate line SLb may include, for example, aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may include a single layer or multiple layers including one or more of the above-described materials.

A second interlayer insulating layer 116 may be disposed on the third semiconductor layer A3 and the upper gate line SLb. The second gate insulating layer 116 may include an inorganic insulating layer including an inorganic insulating material, such as silicon oxide, silicon nitride, and/or silicon oxynitride, and may have a single-layer or multi-layered structure including one or more of the above-described materials.

The node connection electrode 166 and the connection electrode NM may be disposed on the second interlayer insulating layer 116. The node connection electrode 166 and the connection electrode NM may be referred to as a fourth metal layer in the present disclosure. The node connection electrode 166 and the connection electrode NM may include, for example, aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may include a single layer or multiple layers including one or more of the above-described materials. The node connection electrode 166 and the connection electrode NM may be disposed at (e.g., in or on) the same layer as each other, and may include the same material as each other.

The connection electrode NM may electrically connect the first semiconductor layer A1 of the first transistor T1 to the third semiconductor layer A3 of the third transistor T3. The connection electrode NM may be connected to a portion of the first semiconductor layer A1 through the first contact hole CNT1, and may be connected to a portion of the third semiconductor layer A3 through the second contact hole CNT2. The first contact hole CNT1 may pass through (e.g., may penetrate) the inorganic insulating layers between the first semiconductor layer A1 and the connection electrode NM, for example, such as the first gate insulating layer 112, the second gate insulating layer 113, the first interlayer insulating layer 114, and the second interlayer insulating layer 116. The second contact hole CNT2 may pass through (e.g., may penetrate) the second interlayer insulating layer 116 between the third semiconductor layer A3 and the connection electrode NM.

The node connection electrode 166 may electrically connect the first gate electrode G1 of the first transistor T1 to the third semiconductor layer A3 of the third transistor T3. The node connection electrode 166 may be connected to a portion of the first gate electrode G1 through the third contact hole CNT3, and may be connected to a portion of the third semiconductor layer A3 through the fourth contact hole CNT4. The third contact hole CNT3 may pass through (e.g., may penetrate) the inorganic insulating layers between the first gate electrode G1 and the node connection electrode 166, for example, such as the second gate insulating layer 113, the first interlayer insulating layer 114, and the second interlayer insulating layer 116. The fourth contact hole CNT4 may pass through (e.g., may penetrate) the second interlayer insulating layer 116 between the third semiconductor layer A3 and the node connection electrode 166.

As shown in FIG. 4, a depth of the first contact hole CNT1 is greater than a depth of the second contact hole CNT2. A portion of the first gate insulating layer 112, a portion of the second gate insulating layer 113, a portion of the first interlayer insulating layer 114, and a portion of the second interlayer insulating layer 116 may be etched to form the first contact hole CNT1. A portion of the second interlayer insulating layer 116 may be etched to form the second contact hole CNT2. Accordingly, an etching process time used to form the first contact hole CNT1 may be longer than an etching process time used to form the second contact hole CNT2. Thus, when etching processes for forming the first contact hole CNT1 and the second contact hole CNT2 are concurrently (e.g., simultaneously or substantially simultaneously) performed with each other, at least the etching process time for forming the first contact hole CNT1 may be secured.

Similarly, a depth of the third contact hole CNT3 is greater than a depth of the fourth contact hole CNT4. A portion of the second gate insulating layer 113, a portion of the first interlayer insulating layer 114, and a portion of the second interlayer insulating layer 116 may be etched to form the third contact hole CNT3. A portion of the second interlayer insulating layer 116 may be etched to form the fourth contact hole CNT4. An etching process time used to form the third contact hole CNT3 may be longer than an etching process time used to form the fourth contact hole CNT4. Thus, when etching processes for forming the third contact hole CNT3 and the fourth contact hole CNT4 are concurrently (e.g., simultaneously or substantially simultaneously) performed with each other, at least the etching process time for forming the third contact hole CNT3 may be secured.

According to a comparative example, because the etching process times used to form the first contact hole CNT1 and the third contact hole CNT3 may be longer than the etching process times used to form the second contact hole CNT2 and the fourth contact CNT4, respectively, over-etching may occur in a region where the second contact hole CNT2 and the fourth contact hole CNT4 are formed, and thus, the third semiconductor layer A3 may be damaged.

According to one or more embodiments of the present disclosure, as the display apparatus includes the second gate insulating layer 113 and/or the first interlayer insulating layer 114 including the inorganic insulating materials including the first dopant DP1, the over-etching of the second and fourth contact holes CNT2 and CNT4 described above may be prevented, minimized, or reduced. For example, the second gate insulating layer 113 and/or the first interlayer insulating layer 114 may both be doped (e.g., may be equally doped) with the first dopant DP1. The first dopant DP1 may include fluorine.

The second gate insulating layer 113 and the first interlayer insulating layer 114 may include an inorganic insulating layer containing at least one of silicon oxide (SiOₓ), silicon nitride (SiNₓ), or silicon oxynitride (SiOₓN_{y}). In order to form a contact hole in (e.g., penetrating) the second gate insulating layer 113 and the first interlayer insulating layer 114, a portion of a corresponding layer may be etched (e.g., dry etched). In a dry etching process of the second gate insulating layer 113 and the first interlayer insulating layer 114, at least one of CF₄ gas, CHF₃ gas, C₂HF₅ gas, or CH₂F₂ gas may be used to etch the insulating layer. When a dry etching process is performed using CF₄ gas, for example, an inorganic insulating layer, such as a silicon oxide (SiOₓ) layer, may be etched as the inorganic insulating layer reacts with silicon (Si) and fluorine (F), and is vaporized into the form of silicon tetrafluoride (SiF₄).

When the inorganic insulating layer is doped with fluorine (F), as the ratio of fluorine (F) increases during the dry etching process, a reaction rate is increased (e.g., is relatively fast), and the processing time used for the etching process may be decreased (e.g., may be shortened). When the depths of the contact holes are different from one another as in the present embodiment, and the doping process is performed with fluorine (F) in the insulating layer(s) through which a relatively deep contact hole passes (e.g., penetrates), fluorine (F)-doped insulating layer(s) may have an increased etch rate, and thus, the etching time thereof may be decreased (e.g., may be shortened). As a result, as the duration of the etching process of the relatively deeper contact hole is reduced, over-etching in the regions with relatively shallower contact holes may be reduced. In addition, as a doping process is performed on the insulating layers, the semiconductor layers may not be affected, and thus, damage due to the over-etching may be prevented or substantially prevented without changing transistor (e.g., thin-film transistor TFT) characteristics.

Still referring to FIG. 4, in an embodiment, the first contact hole CNT1 and the third contact hole CNT3 may pass through (e.g., may penetrate) the second gate insulating layer 113, the first interlayer insulating layer 114, and the second interlayer insulating layer 116. The second contact hole CNT2 and the fourth contact hole CNT4 pass through (e.g., may penetrate) the second interlayer insulating layer 116. The depths of the first contact hole CNT1 and the third contact hole CNT3 are greater than the depths of the second contact hole CNT2 and the fourth contact hole CNT4, and thus, a longer etching process time may be used to form the first and third contact holes CNT3. However, when a doping process is performed using fluorine (F) on the second gate insulating layer 113 and/or the first interlayer insulating layer 114 through which the first contact hole CNT1 and the third contact hole CNT3 pass (e.g., penetrate), an etching process time for forming the first contact hole CNT1 and the third contact hole CNT3 may be decreased (e.g., may be shortened). Accordingly, over-etching in the regions where the second contact hole CNT2 and the fourth contact hole CNT4 are disposed may be prevented or substantially prevented, and damage to and deterioration of the third semiconductor layer A3 may be prevented or substantially prevented.

The higher the concentration of fluorine (F) implanted into each insulating layer, the faster the etch rate. Therefore, the higher the doping concentration of the first dopant DP1, the shorter the etching process time. In an embodiment, a dose amount of the first dopant DP1 may be about 1.0×E¹¹ atoms/cm² to about 1.0×E¹⁵ atoms/cm². A dose amount of the first dopant DP1 implanted into each insulating layer may be about 1.0×E¹⁴ atoms/cm² to about 1.0×E¹⁵ atoms/cm².

In an embodiment, the first dopant DP1 may be implanted into the second gate insulating layer 113 at a first accelerating voltage, and may be implanted into the first interlayer insulating layer 114 at a second accelerating voltage. A location of the first dopant DP1 may be adjusted by the acceleration voltage during the doping. In other words, the higher the acceleration voltage of a doping process, the greater a distance from the upper surface of each insulating layer to a location where a dopant is implanted. The doping process may be performed on each of the second gate insulating layer 113 and the first interlayer insulating layer 114, and because a thickness of the first interlayer insulating layer 114 may be greater than a thickness of the second gate insulating layer 113, the first accelerating voltage may be greater than the second accelerating voltage. In some embodiments, the first acceleration voltage for implanting the first dopant DP1 into the second gate insulating layer 113 may be about 10 KeV to about 20 KeV, and the second acceleration voltage for implanting the first dopant DP1 into the first interlayer insulating layer 114 may be about 20 KeV to about 70 KeV.

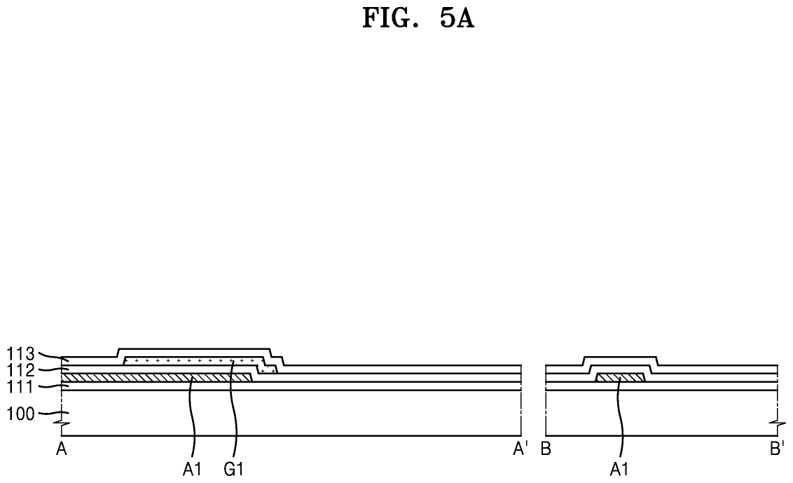

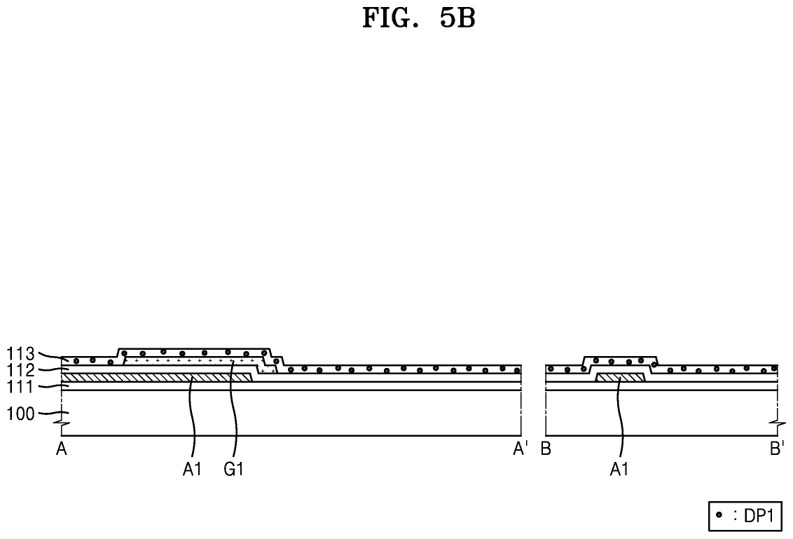

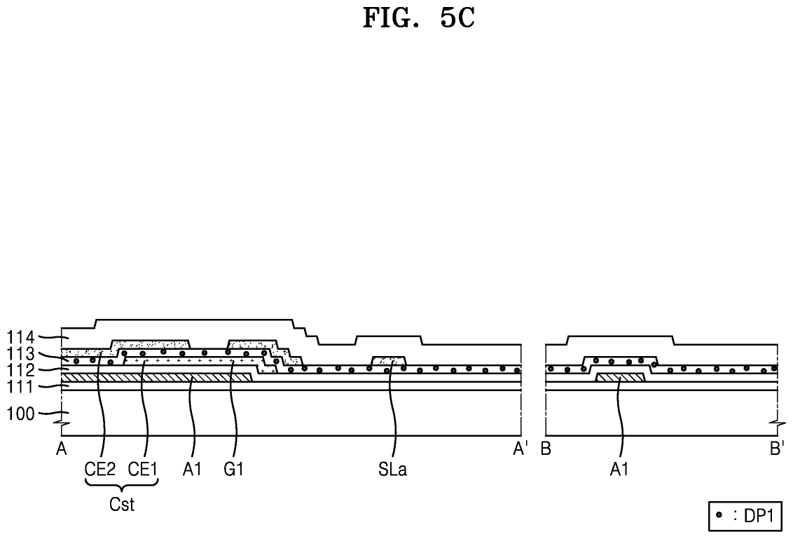

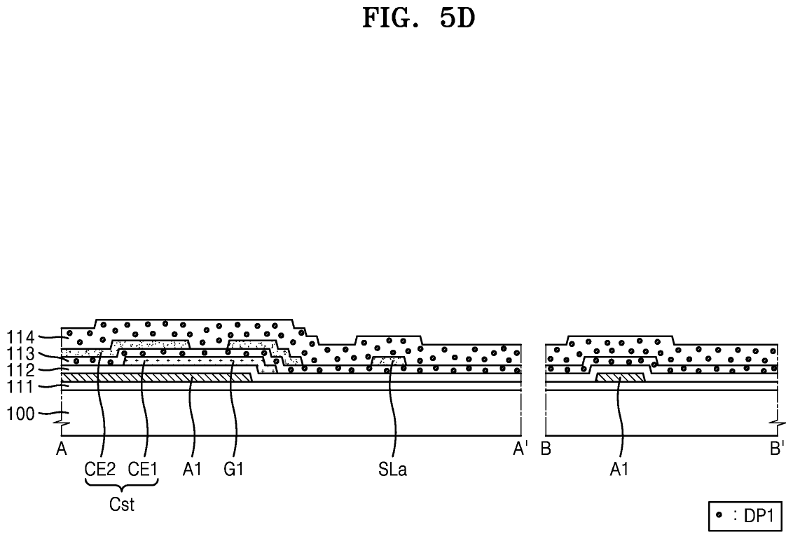

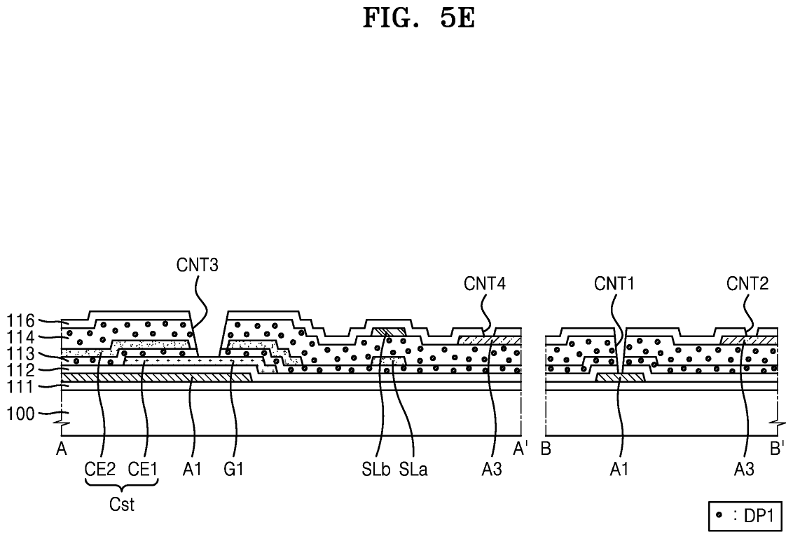

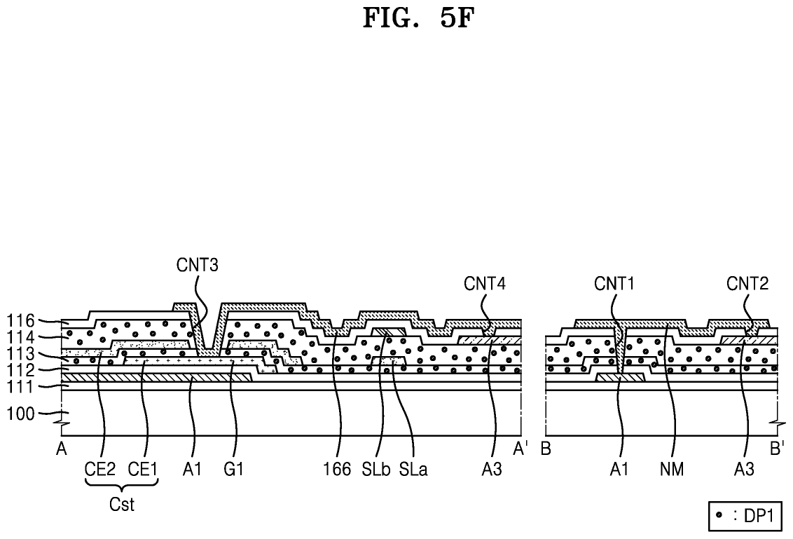

FIGS. 5A through 5F are schematic cross-sectional views sequentially illustrating various processes of a method of manufacturing a thin-film transistor substrate, according to an embodiment.

Referring to FIG. 5A, the buffer layer 111, the first semiconductor layer A1, the first gate insulating layer 112, the first gate electrode G1, and the second gate insulating layer 113 may be sequentially stacked on the substrate 100. As described above, the first gate insulating layer 112 and the second gate insulating layer 113 may include an inorganic insulating layer containing at least one of silicon oxide (SiOₓ), silicon nitride (SiNₓ), or silicon oxynitride (SiOₓN_{y}). A thickness of the second gate insulating layer 113 may be about 1000 Å to about 1300 Å.

Referring to FIG. 5B, the first dopant DP1 may be implanted into the second gate insulating layer 113. When a doping process is performed on the second gate insulating layer 113, the first dopant DP1 may be implanted at a first concentration and a first acceleration voltage. For example, the first dopant DP1 may include fluorine (F), the first concentration of the first dopant DP1 may be about 1.0×E¹⁴ atoms/cm² to about 1.0×E¹⁵ atoms/cm², and the first acceleration voltage may be about 10 KeV to about 20 KeV. However, the first concentration and the first acceleration voltage are not limited to the above example ranges.

Referring to FIG. 5C, the upper electrode CE2 of the storage capacitor Cst and the lower gate line SLa may be formed on the second gate insulating layer 113 that is doped with the first dopant DP1. The first interlayer insulating layer 114 may be formed to cover the upper electrode CE2 and the lower gate line SLa. The first interlayer insulating layer 114 may include an inorganic insulating layer including at least one of silicon oxide (SiOₓ), silicon nitride (SiNₓ), or silicon oxynitride (SiOₓN_{y}). A thickness of the first interlayer insulating layer 114 may be about 4500 Å to about 5500 Å.

Referring to FIG. 5D, the first dopant DP1 may be implanted into the first interlayer insulating layer 114. When a doping process is performed on the first interlayer insulating layer 114, the first dopant DP1 may be implanted at a second concentration and a second acceleration voltage. For example, the first dopant DP1 may include fluorine (F), the second concentration of the first dopant DP1 may be about 1.0×E¹⁴ atoms/cm² to about 1.0×E¹⁵ atoms/cm², and the second acceleration voltage may be about 20 KeV to about 70 KeV. However, the second concentration and the second acceleration voltage are not limited to the above example ranges.

Referring to FIG. 5E, the third semiconductor layer A3 and the upper gate line SLb may be formed on the first interlayer insulating layer 114 that is doped with the first dopant DP1. The upper gate line SLb may extend to include the upper gate electrode G3b of the third transistor T3 (e.g., see FIG. 3), and thus, the third gate insulating layer (not shown) may be additionally formed between the third semiconductor layer A3 and the upper gate electrode G3b of the third transistor T3. The second interlayer insulating layer 116 may be disposed on the third semiconductor layer A3 to cover the upper gate line SLb.

After the second interlayer insulating layer 116 is formed, a dry etching process of forming the contact holes in the plurality of insulating layers may be performed. The first contact hole CNT1, the second contact hole CNT2, the third contact hole CNT3, and the fourth contact hole CNT4 illustrated in FIG. 5E may be formed through a dry etching process. The first contact hole CNT1 may pass through (e.g., may penetrate) the first gate insulating layer 112, the second gate insulating layer 113, the first interlayer insulating layer 114, and the second interlayer insulating layer 116 to expose the first semiconductor layer A1. The second contact hole CNT2 may pass through (e.g., may penetrate) the second interlayer insulating layer 116 to expose the third semiconductor layer A3. The third contact hole CNT3 may pass through (e.g., may penetrate) the second gate insulating layer 113, the first interlayer insulating layer 114, and the second interlayer insulating layer 116 to expose the first gate electrode G1. The fourth contact hole CNT4 may pass through (e.g., may penetrate) the second interlayer insulating layer 116 to expose the third semiconductor layer A3.

According to one or more embodiments, as the second gate insulating layer 113 and the first interlayer insulating layer 114 are doped with fluorine (F), the duration of the dry etching process of forming the first contact hole CNT1 and the third contact hole CNT3 may be decreased (e.g., may be shortened) compared to a case when fluorine (F) is not doped. Accordingly, over-etching that may occur while forming the second contact hole CNT2 and the fourth contact hole CNT4 may be prevented or substantially prevented.

Referring to FIG. 5F, the connection electrode NM and the node connection electrode 166 may be formed on the second interlayer insulating layer 116. The connection electrode NM and the node connection electrode 166 may be formed to fill the plurality of contact holes, and may be electrically connected to the lower layers exposed by the contact holes, respectively. In more detail, the connection electrode NM may be connected to the first semiconductor layer A1 through the first contact hole CNT1, and may be connected to the third semiconductor layer A3 through the second contact hole CNT2. The node connection electrode 166 may be connected to the first gate electrode G1 through the third contact hole CNT3, and may be connected to the third semiconductor layer A3 through the fourth contact hole CNT4.

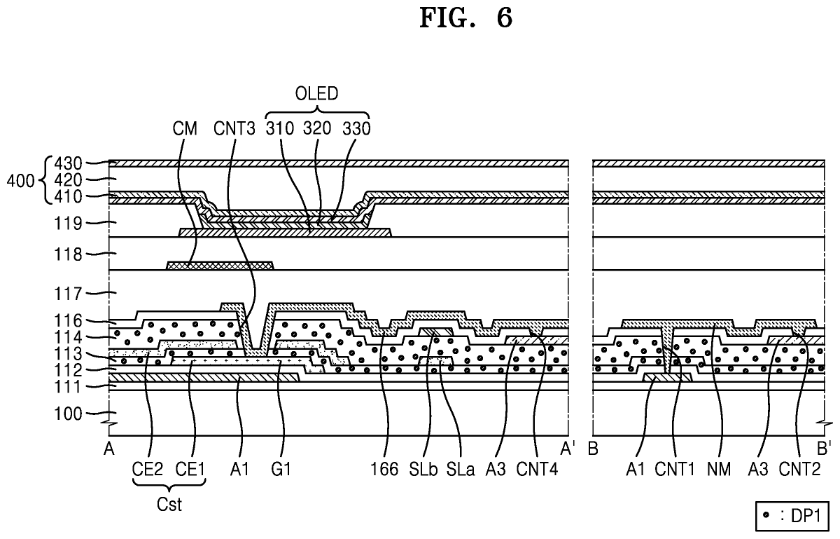

FIG. 6 is a schematic cross-sectional view of a display apparatus according to an embodiment. In FIG. 6, the same reference numerals are used to refer to the same or substantially the same members as those described above with reference to FIG. 4, and thus, redundant description thereof may not be repeated.

Referring to FIG. 6, a display apparatus may include the substrate 100, the sub-pixel circuit PC (e.g., see FIG. 2A) disposed on the substrate 100, the organic light-emitting diode OLED electrically connected to the sub-pixel circuit PC, and a thin-film encapsulation layer 400 covering these members. The sub-pixel circuit PC may include the first to seventh thin-film transistors T1 to T7, and the storage capacitor Cst.

A first planarization layer 117 may be formed on the connection electrode NM and the node connection electrode 166. The first planarization layer 117 may be formed as a single layer or multiple layers including an organic material or an inorganic material. In an embodiment, the first planarization layer 117 may include a general-purpose polymer, such as benzocyclobutene (BCB), polyimide (PI), hexamethyldisiloxane (HMDSO), poly(methylmethacrylate) (PMMA), or polystyrene (PS), a polymer derivative with a phenolic group, acrylic polymers, imide-based polymers, arylether-based polymers, amide-based polymers, fluorine-based polymers, p-xylene-based polymers, vinyl alcohol-based polymers, and/or a suitable blend thereof. The first planarization layer 117 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), and/or the like.

A conductive layer CM may be disposed on the first planarization layer 117. The conductive layer CM may include a connection electrode electrically connecting an electrode of one of the plurality of transistors of the sub-pixel circuit PC to a pixel electrode 310. The conductive layer CM may include aluminum (Al), copper (Cu), titanium (Ti), and/or the like, and may be formed as multi-layers or a single layer.

A second planarization layer 118 may be disposed on the conductive layer CM. The second planarization layer 118 may be formed as a single layer or multiple layers including an organic material or an inorganic material. In an embodiment, the second planarization layer 118 may include the same or substantially the same material as that of the first planarization layer 117. In another embodiment, the second planarization layer 118 may include a material different from that of the first planarization layer 117.

The organic light-emitting diode OLED including the pixel electrode 310, an intermediate layer 320, and an opposite electrode 330, may be disposed on the second planarization layer 118.

The pixel electrode 310 may be disposed on the second planarization layer 118. The pixel electrode 310 may include a (semi)-light transmissive electrode or a reflective electrode. The pixel electrode 310 may include a reflective layer including aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), copper (Cu), and/or a suitable compound thereof, and a transparent or semi-transparent electrode layer formed on the reflective layer. The transparent or semi-transparent electrode layer may include at least one selected from among indium tin oxide (ITO), indium zinc oxide (IZO), zinc oxide (ZnO), indium oxide (In₂O₃), indium gallium oxide (IGO), and aluminum zinc oxide (AZO). The pixel electrode 310 may have a stacked structure including ITO/Ag/ITO.

A bank layer 119 may be disposed on the second planarization layer 118, and the bank layer 119 may have an opening exposing at least a portion of the pixel electrode 310. A region exposed by the opening of the bank layer 119 may be defined as an emission area. The bank layer 119 may prevent or substantially prevent the occurrence of an arc at the edge of the pixel electrode 310, by increasing a distance between the opposite electrode 330 and the pixel electrode 310. The bank layer 119 may include an organic insulating material, such as polyimide, polyamide, acrylic resin, BCB, HMDSO, and/or a phenol resin, for example, by spin coating or the like.

The intermediate layer 320 may be disposed on the pixel electrode 310, which is at least partially exposed by the bank layer 119. The intermediate layer 320 may include a low molecular material or a high molecular material, and may emit red, green, blue, or white light. When a low molecular material is included, a hole injection layer (HIL), a hole transport layer (HTL), an emission layer (EML), an electron transport layer (ETL), an electron injection layer (EIL), and/or the like may have a single layer structure or a multiple stacked structure, and may include various suitable organic materials, such as copper phthalocyanine (CuPc), N,N-di(naphthalen-1-yl)-N,N′-diphenyl-benzidine (NPB), tris-8-hydroxyquinoline aluminum (Alq3), and/or the like. These layers may be formed by a vacuum deposition method.

When the intermediate layer 320 includes a polymer material, the intermediate layer 320 may have a structure including an HTL and an EML. The HTL may include poly(3,4-ethylenedioxythiophene) (PEDOT), and the EML may include a polymer material, such as poly-phenylenevinylene (PPV) and/or polyfluorene. The intermediate layer 320 may be formed by a screen printing method, an inkjet printing method, a laser induced thermal imaging (LITI) method, or the like.

However, the intermediate layer 320 is not limited thereto, and may have various suitable structures. In addition, the intermediate layer 320 may include an integral layer formed as a single body over a plurality of pixel electrodes 310, or may include a layer that is patterned to correspond to each of the plurality of pixel electrodes 310.

The opposite electrode 330 may be disposed on the intermediate layer 320. The opposite electrode 330 may include a conductive material having a low work function. For example, the opposite electrode 330 may include a (semi)transparent layer including silver (Ag), magnesium (Mg), aluminum (Al), platinum (Pt), lithium (Li), calcium (Ca), or a suitable alloy thereof. As another example, the opposite electrode 330 may further include a layer, such as ITO, IZO, ZnO or In₂O₃, on the (semi)transparent layer including one or more of the above-described materials. The opposite electrode 330 may be integrally formed as a single body with respect to a plurality of organic light-emitting diodes to correspond to a plurality of pixel electrodes 310.

The thin-film encapsulation layer 400 may be disposed on the organic light-emitting diode OLED. As the organic light-emitting diode OLED may be damaged (e.g., easily damaged)_by moisture and/or oxygen from the outside, the organic light-emitting diode OLED may be covered with the thin-film encapsulation layer 400 to be protected thereby. The thin-film encapsulation layer 400 may cover the display area, and may extend to the outside of the display area. The thin-film encapsulation layer 400 may include at least one inorganic encapsulation layer, and at least one organic encapsulation layer. For example, the thin-film encapsulation layer 400 may include a first inorganic encapsulation layer 410, an organic encapsulation layer 420, and a second inorganic encapsulation layer 430.

The first inorganic encapsulation layer 410 may cover the opposite electrode 330. The first inorganic encapsulation layer 410 may include, for example, silicon oxide (SiO₂), silicon nitride (SiNₓ), silicon oxynitrde SiON, or the like. In some embodiments, other suitable layers, such as a capping layer, may be further formed between the first inorganic encapsulation layer 410 and the opposite electrode 330, as needed or desired. Because the first inorganic encapsulation layer 410 may be formed along a structure located therebelow, an upper surface of the first inorganic encapsulation layer 410 may not be flat or substantially flat (e.g., may not be planar). The organic encapsulation layer 420 may cover the first inorganic encapsulation layer 410, and may have an approximately planar (e.g., a flat or substantially flat) upper surface, unlike that of the first inorganic encapsulation layer 410. In more detail, the organic encapsulation layer 420 may have an approximately planar upper surface in a portion corresponding to the display area. The organic encapsulation layer 420 may include one or more materials selected from polyethylene terephthalate, polyethylene naphthalate, polycarbonate, polyimide, polyethylene sulfonate, polyoxymethylene, polyarylate, and hexamethyldisiloxane. The second inorganic encapsulation layer 430 may cover the organic encapsulation layer 420, and may include, for example, silicon oxide (SiO₂), silicon nitride (SiNₓ), silicon oxynitrde (SiON), or the like.

When cracks occur in the thin-film encapsulation layer 400, the thin-film encapsulation layer 400 may prevent or substantially prevent a connection of the cracks between the first inorganic encapsulation layer 410 and the organic encapsulation layer 420, or between the organic encapsulation layer 420 and the second inorganic encapsulation layer 430. Accordingly, a formation of a path through which moisture and/or oxygen from the outside may penetrate into the organic light-emitting diode OLED may be prevented or substantially prevented.

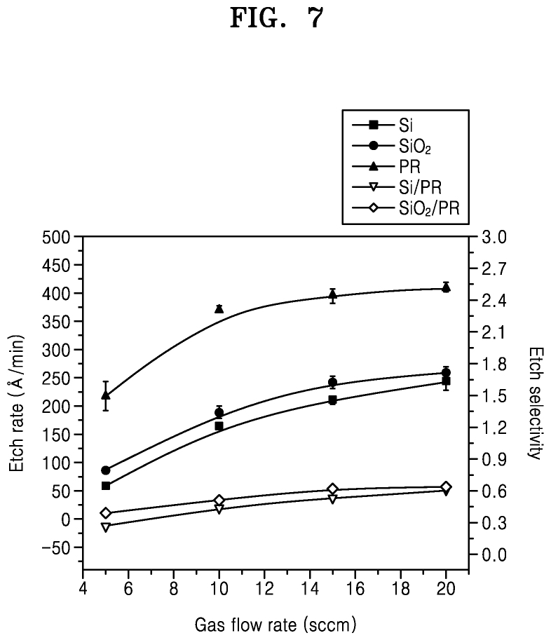

FIG. 7 is a graph illustrating a comparison of etch rates according to a doping concentration in a display apparatus, according to an embodiment.

FIG. 7 is a graph showing an etch rate and an etch selectivity that may vary when a gas concentration is increased with respect to silicon (Si), silicon oxide (SiO₂), a photoresist (PR), a mixture of silicon (Si) and the photoresist (PR), and a mixture of silicon oxide (SiO₂) and the photoresist (PR). The horizontal axis of the graph denotes a gas flow rate, which is the volume of gas that passes through a certain point in a certain period, and the gas includes fluorine (F) as the first dopant DP1. In other words, the horizontal axis of the graph denotes a value proportional to the concentration of fluorine (F). The left vertical axis of the graph indicates the etch rate, or in other words, the etched thickness versus the etch time, and the unit shown is A/min. The right vertical axis of the graph indicates an etch selectivity ratio, or in other words, the etch rate of a material desired to be etched compared to the etch rate of a material that is not to be etched.

Referring to FIG. 7, the etch rate and the etch selectivity lowers (e.g., decreases) in the order of the photoresist (PR), silicon oxide (SiO₂), silicon (Si), the mixture of silicon oxide (SiO₂) and the photoresist (PR), and the mixture of silicon (Si) and the photoresist (PR).

However, in all of the photoresist (PR), silicon oxide (SiO₂), silicon (Si), the mixture of silicon oxide (SiO₂) and the photoresist (PR), and the mixture of silicon (Si) and the photoresist (PR), as the gas flow rate increases, the etch rate and the etch selectivity thereof increases (e.g., are improved). In other words, as the concentration of fluorine (F) increases, an etching reaction may be more smoothly performed.

The materials such as silicon oxide (SiO₂) and/or silicon (Si) are materials included in the second gate insulating layer 113 and the first interlayer insulating layer 114 as described above. In other words, as illustrated in FIG. 7, the higher the concentration of the first dopant DP1 (e.g., fluorine (F)) implanted into the second gate insulating layer 113 and the first interlayer insulating layer 114, the higher the etch rate, and thus, a processing time used for the etching process may be reduced (e.g., may be shortened).

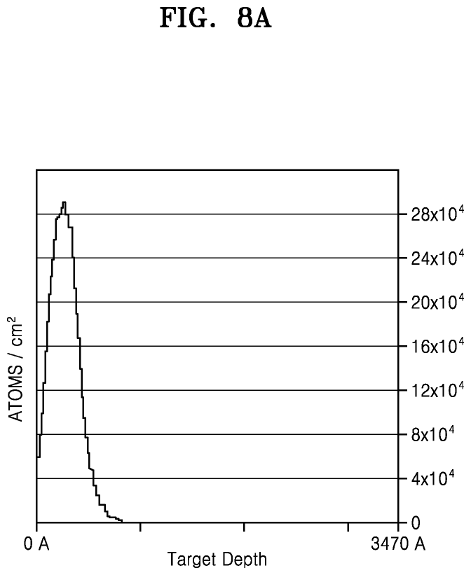

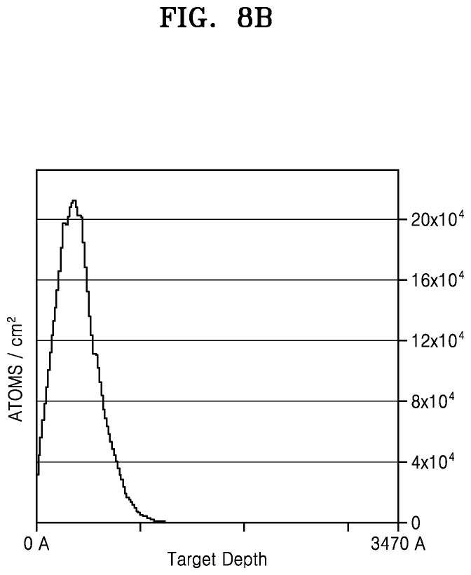

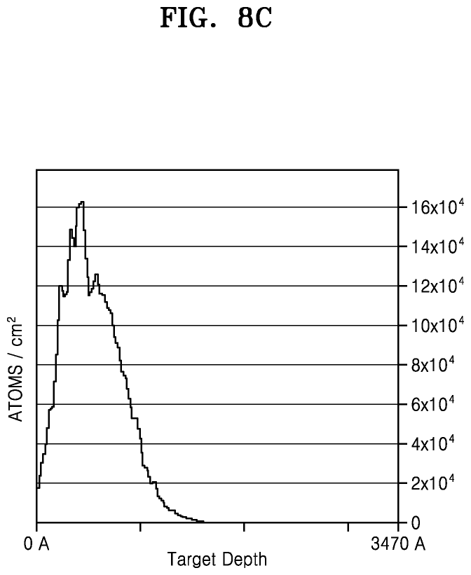

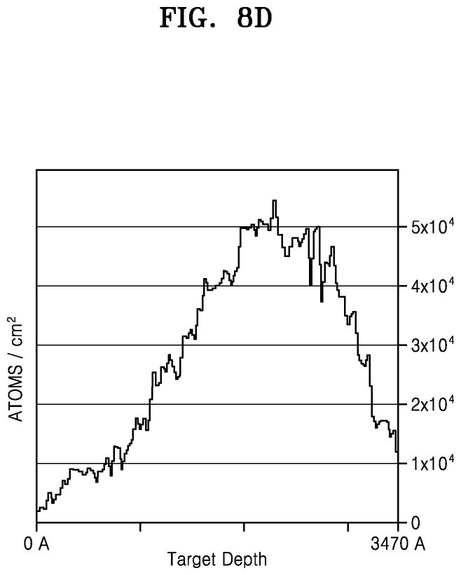

FIGS. 8A through 8D are graphs illustrating a position in a display apparatus where a dopant is implanted, according to an embodiment.

FIGS. 8A through 8D are graphs showing measured concentration distributions of the first dopant DP1 in a depth direction from an upper surface of an insulating layer, such as the second gate insulating layer 113 and the first interlayer insulating layer 114, through which the first dopant DP1 is implanted. The first dopant DP1 is fluorine (F).

FIG. 8A shows a concentration distribution of the first dopant DP1 according to a depth of an insulating layer in which the first dopant DP1 is implanted at an acceleration voltage of 10 KeV. FIG. 8B shows the concentration distribution of the first dopant DP1 according to a depth of an insulating layer in which the first dopant DP1 is implanted at an acceleration voltage of 10 KeV. FIG. 8C shows the concentration distribution of the first dopant DP1 according to a depth of an insulating layer in which the first dopant DP1 is implanted at an acceleration voltage of 20 KeV. FIG. 8D shows the concentration distribution of the first dopant DP1 according to a depth of an insulating layer in which the first dopant DP1 is implanted at an acceleration voltage of 70 KeV.

The horizontal axis of the graphs of FIGS. 8A through 8D denotes the depth in units of Å. The depth is increased toward the left side on the horizontal axis of the graphs. The vertical axis of the graphs denotes the number of dopant atoms included in a unit area in units of atoms/cm².

Referring to FIG. 8A, when the first dopant DP1 is implanted at an acceleration voltage of 10 KeV, most of the first dopant DP1 is disposed at a depth of about 0 Å to about 700 Å with respect to an upper surface of an insulating layer, and a maximum concentration value of the first dopant DP1 is formed at a depth of about 250 Å to about 270 Å.

Referring to FIG. 8B, when the first dopant DP1 is implanted at an acceleration voltage of 15 KeV, most of the first dopant DP1 is disposed at a depth of about 0 Å to about 1200 Å with respect to an upper surface of the insulating layer, and a maximum concentration value of the first dopant DP1 is formed at a depth of about 370 Å to about 400 Å.

Referring to FIG. 8C, when the first dopant DP1 is implanted at an acceleration voltage of 20 KeV, most of the first dopant DP1 is disposed at a depth of about 0 Å to about 1600 Å with respect to an upper surface of an insulating layer, and a maximum concentration value of the first dopant DP1 is formed at a depth of about 510 Å to about 550 Å.

Referring to FIG. 8D, when the first dopant DP1 is implanted at an acceleration voltage of 70 KeV, most of the first dopant DP1 is disposed at a depth of about 0 Å to about 3500 Å with respect to an upper surface of an insulating layer, and a maximum concentration value of the first dopant DP1 is formed at a depth of about 1800 Å to about 2200 Å.

As illustrated by these graphs, by adjusting the amplitude of the acceleration voltage used in a doping process, a location of a dopant being doped may be adjusted. Accordingly, when implanting a dopant in a relatively thicker layer, a relatively larger acceleration voltage may be used to perform the doping process.

In an embodiment, a thickness of the second gate insulating layer 113 may be about 1000 Å to about 1300 Å, and a thickness of the first interlayer insulating layer 114 may be about 4500 Å to about 5500 Å. Here, a dopant is implanted as uniformly as possible when the maximum concentration of the dopant is implanted into the middle depth of each layer, and thus, the second acceleration voltage that is used when the doping process is performed on the first interlayer insulating layer 114 may have a greater value than the first acceleration voltage that is used when the doping process is performed on the second insulating layer 113 Accordingly, the first acceleration voltage used when the first dopant DP1 is implanted into the second gate insulating layer 113 may be about 10 KeV to about 20 KeV, and the second acceleration voltage used when the first dopant DP1 is implanted into the first interlayer insulating layer 114 may be about 20 KeV to about 70 KeV. However, the first acceleration voltage and the second acceleration voltage are not limited to the above example ranges.

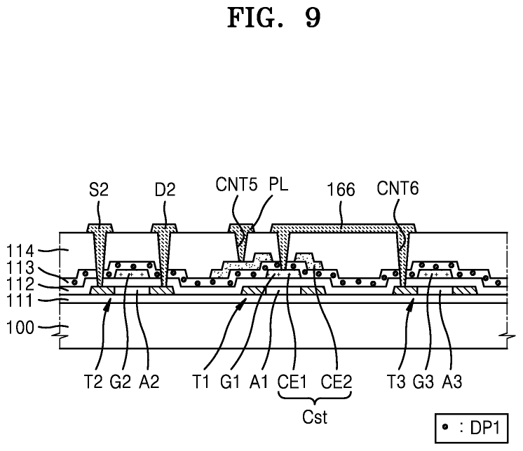

FIG. 9 is a schematic cross-sectional view of a thin-film transistor substrate according to an embodiment. Referring to FIG. 9, the thin-film transistor substrate may have the same or substantially the same features as those described above with reference to FIG. 4, except the third transistor T3, the first interlayer insulating layer 114, the node connection electrode 166, and the driving voltage line PL may be different. Accordingly redundant description of the same or substantially the same components as those described above with reference to FIG. 4 may not be repeated, and the differences therebetween may be mainly described hereinafter.

Semiconductor layers of a plurality of transistors may be disposed on the buffer layer 111. For example, FIG. 9 illustrates that the first semiconductor layer A1 of the first transistor T1, the second semiconductor layer A2 of the second transistor T2, and the third semiconductor layer A3 of the third transistor T3 are disposed on the buffer layer 111. The first semiconductor layer A1, the second semiconductor layer A2, and the third semiconductor layer A3 may include a silicon-based semiconductor material, for example, such as polysilicon. The first gate insulating layer 112 may be disposed to cover the first semiconductor layer A1, the second semiconductor layer A2, and the third semiconductor layer A3.

The first gate electrode G1 of the first transistor T1, the lower electrode CE1 of the storage capacitor Cst, the second gate electrode G2 of the second transistor T2, and the third gate electrode G3 of the third transistor T3 may be disposed on the first gate insulating layer 112. The first gate electrode G1 may be integrally formed as a single body with the lower electrode CE1 of the storage capacitor Cst. The first gate electrode G1, the second gate electrode G2, and the third gate electrode G3 may be referred to as a first metal layer.

The second gate insulating layer 113 may be disposed on the first gate electrode G1, the second gate electrode G2, and the third gate electrode G3. The second gate insulating layer 113 may include an inorganic insulating layer including an inorganic insulating material, such as silicon oxide, silicon nitride, and/or silicon oxynitride, and may have a single-layer or multi-layered structure including one or more of the above-described materials.

The upper electrode CE2 of the storage capacitor Cst may be disposed on the second gate insulating layer 113. The upper electrode CE2 of the storage capacitor Cst may be referred to as a second metal layer. The upper electrode CE2 of the storage capacitor Cst may overlap with the first gate electrode G1 and/or the lower electrode CE1 of the storage capacitor Cst. The upper electrode CE2 of the storage capacitor Cst may include a hole, such that the node connection electrode 166, which is for electrically connecting the first gate electrode G1 of the first transistor T1 to the third transistor T3, may be connected to the first gate electrode G1.

The first interlayer insulating layer 114 may be disposed on the upper electrode CE2 of the storage capacitor Cst. The first interlayer insulating layer 114 may include an inorganic insulating layer including an inorganic insulating material, such as silicon oxide, silicon nitride, and/or silicon oxynitride, and may have a single-layer or multi-layered structure including one or more of the above-described materials.

The node connection electrode 166, the driving voltage line PL, and a source electrode S2 and a drain electrode D2 of the second transistor T2 may be disposed on the first interlayer insulating layer 114. The node connection electrode 166, the driving voltage line PL, the source electrode S2, and/or the drain electrode D2 may be referred to as a fifth metal layer in the present disclosure. The node connection electrode 166, the driving voltage line PL, the source electrode S2 of the second transistor T2, and the drain electrode D2 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may be formed as a single layer or multiple layers including one or more of the above-described materials. The node connection electrode 166, the driving voltage line PL, the source electrode S2, and the drain electrode D2 may be disposed at (e.g., in or on) the same layer as each other, and may include the same material as each other.

The node connection electrode 166 may electrically connect the first gate electrode G1 of the first transistor T1 to the third semiconductor layer A3 of the third transistor T3. The node connection electrode 166 may be connected to a portion of the first gate electrode G1 through a contact hole, and may be connected to a portion of the third semiconductor layer A3 through a sixth contact hole CNT6. The sixth contact hole CNT6 may pass through (e.g., may penetrate) the first gate insulating layer 112, the second gate insulating layer 113, and the first interlayer insulating layer 114, which are between the third semiconductor layer A3 and the node connection electrode 166.

The driving voltage line PL may be electrically connected to the upper electrode CE2 of the storage capacitor Cst. The driving voltage line PL may be connected to a portion of the upper electrode CE2 of the storage capacitor Cst through a fifth contact hole CNT5. The fifth contact hole CNT5 may pass through (e.g., may penetrate) the first interlayer insulating layer 114 between the upper electrode CE2 and the driving voltage line PL.

Still referring to FIG. 9, a depth of the sixth contact hole CNT6 may be greater than a depth of the fifth contact hole CNT5. A portion of the first gate insulating layer 112, a portion of the second gate insulating layer 113, and a portion of the first interlayer insulating layer 114 may be etched to form the sixth contact hole CNT6. A portion of the first interlayer insulating layer 114 may be etched to form the fifth contact hole CNT5. Accordingly, an etching process time used to form the sixth contact hole CNT6 may be longer than an etching process time used to form the fifth contact hole CNT5. When etching processes for forming the sixth contact hole CNT6 and the fifth contact hole CNT5 are concurrently (e.g., simultaneously or substantially simultaneously) performed, at least an etching process time for forming the sixth contact hole CNT6 may be secured. According to a comparative example, because the etching process time used to form the sixth contact hole CNT6 may be longer than the etching process times used to form the fifth contact hole CNT5, over-etching may occur in the region where the fifth contact hole CNT5 is formed.

According to one or more embodiments of the present disclosure, in the display apparatus, for example, as illustrated in FIG. 9, the first dopant DP1 may be implanted into the second gate insulating layer 113. The first dopant DP1 may include fluorine.

As described above, the second gate insulating layer 113 may include an inorganic insulating layer including at least one of silicon oxide (SiOₓ), silicon nitride (SiNₓ), or silicon oxynitride (SiOₓN_{y}). Also, in a dry etching process of the second gate insulating layer 113, at least one of CF₄ gas, CHF₃ gas, C₂HF₅ gas, or CH₂F₂ gas may be used to etch an insulating layer. Here, when the inorganic insulating layer is doped with fluorine (F), because the ratio of fluorine (F) increases in a dry etching process, a reaction rate may be increased (e.g., may be relatively fast), and thus, a process time used for the etching process may be reduced (e.g., may be shortened).

In more detail, referring to FIG. 9, the sixth contact hole CNT6 passes through (e.g., penetrates) the first gate insulating layer 112, the second gate insulating layer 113, and the first interlayer insulating layer 114. The fifth contact hole CNT5 passes through (e.g., penetrates) the first interlayer insulating layer 114. In other words, the depth of the sixth contact hole CNT6 is greater than the depth of the fifth contact hole CNT5, and thus, a longer processing time may be used for an etching process for forming the sixth contact hole CNT6. When the doping process with fluorine (F) is performed on the second gate insulating layer 113 through which the sixth contact hole CNT6 passes (e.g., penetrates), the etching process time for forming the sixth contact hole CNT6 may be reduced (e.g., may be shortened). Accordingly, over-etching in the region where the fifth contact hole CNT5 is disposed may be prevented or substantially prevented, and damage to and deterioration of the upper electrode CE2 disposed under the fifth contact hole CNT5 may be prevented or substantially prevented.

In the display apparatus according to one or more embodiments of the present disclosure described above, reliability may be improved, and a high-quality display may be implemented by performing doping of an insulating layer, such that over-etching may not occur in the etching process of forming a plurality of contact holes. However, the aspects and features of the present disclosure are not limited to those described above, and the spirit and scope of the present disclosure are not limited to the effects of various embodiments described above.

Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display apparatus comprising:
a substrate;
a buffer layer on the substrate;
a first semiconductor layer on the buffer layer;
a first gate insulating layer on the first semiconductor layer;
a first metal layer on the first gate insulating layer;
a second gate insulating layer on the first metal layer;
a second metal layer on the second gate insulating layer;
a first interlayer insulating layer on the second metal layer; and
a first dopant doped in at least one of the second gate insulating layer or the first interlayer insulating layer.

2. The display apparatus of claim 1, wherein the first dopant comprises fluorine.

3. The display apparatus of claim 1, wherein each of the second gate insulating layer and the first interlayer insulating layer comprises at least one of silicon oxide, silicon nitride, or silicon oxynitride.

4. The display apparatus of claim 1, further comprising:
a second semiconductor layer and a third metal layer on the first interlayer insulating layer;
a second interlayer insulating layer on the second semiconductor layer and the third metal layer; and
a fourth metal layer on the second interlayer insulating layer.

5. The display apparatus of claim 4, wherein:
the fourth metal layer is electrically connected to the first semiconductor layer through a first contact hole penetrating the first gate insulating layer, the second gate insulating layer, the first interlayer insulating layer, and the second interlayer insulating layer;
the fourth metal layer is electrically connected to the second semiconductor layer through a second contact hole penetrating the second interlayer insulating layer; and
a depth of the first contact hole is greater than a depth of the second contact hole.

6. The display apparatus of claim 4, wherein:
the fourth metal layer is electrically connected to the first metal layer through a third contact hole penetrating the second gate insulating layer, the first interlayer insulating layer, and the second interlayer insulating layer;
the fourth metal layer is electrically connected to the second semiconductor layer through a fourth contact hole penetrating the second interlayer insulating layer; and
a depth of the third contact hole is greater than a depth of the fourth contact hole.

7. The display apparatus of claim 4, wherein each of the second gate insulating layer and the first interlayer insulating layer comprises the first dopant, and the second gate insulating layer and the first interlayer insulating layer are located between the first metal layer and the second semiconductor layer.

8. The display apparatus of claim 7, wherein a thickness of the first interlayer insulating layer is greater than a thickness of the second gate insulating layer, and
wherein a first distance from a maximum concentration point of the first dopant to an upper surface of the first interlayer insulating layer in a thickness direction of the first interlayer insulating layer is greater than a second distance from a maximum concentration point of the first dopant to an upper surface of the second gate insulating layer in a thickness direction of the second gate insulating layer.

9. The display apparatus of claim 1, further comprising a fifth metal layer on the first gate insulating layer,
wherein the fifth metal layer is electrically connected to the second metal layer through a fifth contact hole penetrating the first interlayer insulating layer,
wherein the fifth metal layer is electrically connected to the first semiconductor layer through a sixth contact hole penetrating the first gate insulating layer, the second gate insulating layer, the first interlayer insulating layer, and
wherein a depth of the sixth contact hole is greater than a depth of the fifth contact hole.

10. The display apparatus of claim 9, wherein the second gate insulating layer comprises the first dopant, and is located between the first metal layer and the second metal layer.

11. A display apparatus comprising:
a substrate;
a first silicon-based transistor on the substrate, and comprising a first semiconductor layer including a silicon-based semiconductor, and a first gate electrode overlapping with the first semiconductor layer;
at least one insulating layer on the first gate electrode;
a first oxide-based transistor on the at least one insulating layer, and comprising a second semiconductor layer comprising an oxide-based semiconductor; and
a first connection electrode connecting the first semiconductor layer of the first silicon-based transistor to the second semiconductor layer of the first oxide-based transistor,
wherein the first connection electrode is electrically connected to the first semiconductor layer through a first contact hole, and the first connection electrode is electrically connected to the second semiconductor layer through a second contact hole, the first contact hole having a depth different from a depth of the second contact hole, and
wherein an insulating layer from among the at least one insulating layer is located between the first gate electrode and the second semiconductor layer, and comprises an inorganic insulating material doped with a first dopant.

12. The display apparatus of claim 11, wherein the first dopant comprises fluorine.

13. The display apparatus of claim 11, wherein the at least one insulating layer comprises:
a first gate insulating layer on the first semiconductor layer of the first silicon-based transistor;
a second gate insulating layer on the first gate electrode of the first silicon-based transistor; and
a first interlayer insulating layer on the second gate insulating layer,
wherein the first contact hole penetrates the first gate insulating layer, the second gate insulating layer, and the first interlayer insulating layer, and
wherein the second contact hole penetrates the first interlayer insulating layer.

14. The display apparatus of claim 13, further comprising a first node connection electrode connecting the first gate electrode of the first silicon-based transistor to the second semiconductor layer of the first oxide-based transistor,
wherein a depth of a third contact hole for electrically connecting the first node connection electrode to the first gate electrode is different from a depth of a fourth contact hole for electrically connecting the first node connection electrode to the second semiconductor layer.

15. The display apparatus of claim 14, wherein the third contact hole penetrates the second gate insulating layer and the first interlayer insulating layer, and
wherein the fourth contact hole penetrates the first interlayer insulating layer.

16. The display apparatus of claim 13, wherein each of the second gate insulating layer and the first interlayer insulating layer comprises the first dopant, and is located between the first gate electrode and the second semiconductor layer.

17. A method of manufacturing a display apparatus, the method comprising:
forming a buffer layer on a substrate;
forming a first semiconductor layer on the buffer layer;
forming a first gate insulating layer on the first semiconductor layer;
forming a first metal layer on the first gate insulating layer;
forming a second gate insulating layer on the first metal layer; and
implanting a first dopant into the second gate insulating layer at a first acceleration voltage.

18. The method of claim 17, wherein the first dopant comprises fluorine.

19. The method of claim 17, further comprising:
forming a second metal layer on the second gate insulating layer;
forming a first interlayer insulating layer to cover the second metal layer; and
implanting the first dopant into the first interlayer insulating layer at a second acceleration voltage.

20. The method of claim 19, wherein the second acceleration voltage has a greater value than the first acceleration voltage.

21. The method of claim 19, wherein each of a dose amount of the first dopant implanted into the second gate insulating layer and a dose amount of the first dopant implanted into the first interlayer insulating layer has a value in a range from 1.0×E¹⁴ atoms/cm² to 1.0×E¹⁵ atoms/cm².

22. The method of claim 19, wherein the first dopant is implanted into at least a portion of each of the second gate insulating layer and the first interlayer insulating layer by ion implantation or plasma treatment.

23. The method of claim 19, further comprising forming a plurality of contact holes in the second gate insulating layer and the first interlayer insulating layer,
wherein the forming of the plurality of contact holes comprises dry-etching the second gate insulating layer and the first interlayer insulating layer using at least one of CF₄ gas, CHF₃ gas, C₂HF₅ gas, or CH₂F₂ gas.

24. The method of claim 23, wherein a process time of a dry-etching process of the second gate insulating layer and the first gate insulating layer is decreased by the first dopant compared to when the first dopant is not implanted.

25. The method of claim 23, further comprising:
forming a second semiconductor layer and a third metal layer on the first interlayer insulating layer;
forming a second interlayer insulating layer on the second semiconductor layer and the third metal layer; and
forming a fourth metal layer on the second interlayer insulating layer.

26. The method of claim 25, wherein the forming of the plurality of contact holes comprises:
forming a first contact hole penetrating the first gate insulating layer, the second gate insulating layer, the first interlayer insulating layer, and the second interlayer insulating layer; and
forming a second contact hole penetrating the second interlayer insulating layer,
wherein the fourth metal layer is electrically connected to the first semiconductor layer through the first contact hole, and
wherein the fourth metal layer is electrically connected to the second semiconductor layer through the second contact hole.

27. The method of claim 25, wherein the forming of the plurality of contact holes comprises:
forming a third contact hole penetrating the second gate insulating layer, the first interlayer insulating layer, and the second interlayer insulating layer; and
forming a fourth contact hole penetrating the second interlayer insulating layer,
wherein the fourth metal layer is electrically connected to the first metal layer through the third contact hole, and
wherein the fourth metal layer is electrically connected to the second semiconductor layer through the fourth contact hole.
